(19) United States
(12) Patent Application Publication
(10) Pub. No.: US 2002/0056868 A1
(43) Pub. Date: May 16, 2002

(54) Method for fabricating self-aligned dram cell with stack capacitor

(75) Inventor: Tsung-Chih Wu, Hsin-Chu (TW)

Correspondence Address: POWELL, GOLDSTEIN, FRAZER & MURPHY LLP, P.O. BOX 97223, WASHINGTON, DC, 20090-7223, US

(73) Assignee: United Microelectronics Corp.

(21) Appl. No.: 10/043,197

(22) Filed: Jan. 14, 2002

Related U.S. Application Data
(62) Division of application No. 09/669,942, filed on Sep. 26, 2000.

(51) Int. Cl. H01L 29/76; H01L 29/94

(52) U.S. Cl. 257/310

(57) ABSTRACT

A method for fabricating self-aligned DRAM cell with stack capacitor, which is comprised of providing a semiconductor substrate having a plurality of oxide isolation regions and MOS transistors formed thereon, each of the MOS transistors with a cap layer of silicon nitride and a silicon nitride spacer, wherein two adjacent MOS transistors are formed between two oxide isolation regions and the two adjacent MOS transistors share a source/drain region therebetween. Forming a plurality of first oxides on each of the oxide isolation regions and each of the MOS transistors by photolithography and etching method. Thereafter, utilizing photolithography and etching method, forming a plurality of conductive regions of MOS-like structure each of which with a cap layer of silicon nitride and a silicon nitride spacer, across over two first oxides on the two adjacent MOS transistors. Subsequently, forming a plurality of second oxides on each of the first oxides on the oxide isolation regions and each of the conductive regions with MOS-like structure, through photolithography and etching method. Finally, forming a plurality of stack capacitors on the second oxides by way of photolithography and etching method, each of stack capacitors is formed between two oxide isolation regions. Thereby, a plurality of self-aligned DRAM cell with a stack capacitor is provided.

### BACKGROUND OF THE INVENTION

1. Field of the Invention

The present invention relates to a method for fabricating DRAM (dynamic random access memory) cell with stack capacitor, and more particularly to a method for fabricating self-aligned DRAM cell with stack capacitor.

2. Description of the Prior Art

A typical DRAM cell consists of a single transistor and a storage capacitor. Digital information is stored in the capacitor and accessed through the transistor, by way of addressing the desired memory cell, which is connected with other such cells through an array of bit lines and word lines. In order to construct high density DRAMs in a reasonably sized chip area, both the transistor and capacitor elements must occupy less lateral space in each memory cell than in the previous generation DRAM designs. As DRAMs are scaled down in dimensions, there is a continuous challenge to maintain a sufficiently high stored charge per capacitor unit area. Efforts to increase capacitance without increasing the planar area of the capacitor have been concentrated on building three dimensional capacitor structures, which increase the capacitor surface area. Thus, cell structures have had to change from the conventional planar-type capacitors to either trench capacitors or stack capacitors, in particular at densities above 4 Mbit.

In order to provide the large surface area needed, or to increase the capacitance, the capacitor must be formed at a significant height above the substrate. Various shapes of capacitor structures have been used to address this issue. For example, U.S. Pat. No. 5,185,282 to Lee et al. provides a method of fabricating cup-shaped capacitor storage node, and U.S. Pat. No. 5,273,925 to Yamanaka provides a method of fabricating cylindrical capacitor electrode. These capacitor structures can effectively increase the capacitance values of the capacitors, while the processes thereof are too complicated to be practically employed for mass-production.

Accordingly, it is desirable to provide a method for fabricating DRAM cell with stack capacitor having efficiently increased capacitance value, whose process is readily achieved and practically employed for mass-production.

### SUMMARY OF THE INVENTION

It is one object of the present invention to provide a method for fabricating self-aligned DRAM cell with stack capacitor, in which the capacitor area is remarkably increased when compared with the conventional stacked structure DRAM cell, so that the capacitor area efficiency is greatly increased and the process can be executed by such a mask number as the prior stacked structure and the structure thereof is simple.

It is another object of the present invention to provide a method for fabricating self-aligned DRAM cell with stack capacitor, in which the node contact for storage capacitor and the polysilicon gate serving for bit line are self-alignment by way of the processes of photolithography and etching method.

It is a further object of the present invention to provide a method for fabricating self-aligned DRAM cell with stack capacitor, in which a silicon nitride spacer is formed beside each sidewall of the polysilicon gate of bit line for preventing short circuit occurred between the polysilicon gate and one electrode of the stack capacitor.

In order to achieve the above objects, the present invention provides a method for fabricating self-aligned DRAM cell with stack capacitor, which is comprised of providing a semiconductor substrate having a plurality of oxide isolation regions and MOS transistors formed thereon, each of the MOS transistors with a cap layer of silicon nitride and a silicon nitride spacer, wherein two adjacent MOS transistors are formed between two oxide isolation regions and the two adjacent MOS transistors share a source/drain region therebetween. Forming a plurality of first oxides on each of the oxide isolation regions and each of the MOS transistors by photolithography and etching method. Thereafter, utilizing photolithography and etching method, forming a plurality of conductive regions of MOS-like structure each of which with a cap layer of silicon nitride and a silicon nitride spacer, across over two first oxides on the two adjacent MOS transistors. Subsequently, forming a plurality of second oxides on each of the first oxides on the oxide isolation regions and each of the conductive regions with MOS-like structure, through photolithography and etching method. Finally, forming a plurality of stack capacitors on the second oxides by way of photolithography and etching method, each of stack capacitors is formed between two oxide isolation regions. Thereby, a plurality of self-aligned DRAM cell with a stack capacitor is provided.

### BRIEF DESCRIPTION OF THE DRAWINGS

The present invention can be best understood through the following description and accompanying drawings wherein:

FIGS. 1 to 8 shows sectional views of various steps for forming one embodiment of the present invention.

### DESCRIPTION OF THE PREFERRED EMBODIMENT

Preferred embodiment of this invention will be explained with reference to the drawings.

As shown in FIG. 1, a semiconductor substrate 1, for example, P-monocrystalline silicon, is provided. A plurality of oxide isolation regions 2 are formed and served to isolate semiconductor surface regions from other such regions in the substrate 1, for example, two DRAM cells as shown in subsequent drawings. The oxide isolation regions 2 can be a plurality of field oxides (FOX) formed by thermal oxidation process. Also can be a plurality of shallow trench isolations formed by anistropically dry etching method, e.g. performing sputtering etch or reactive ion etch, utilizing CHF₃, C₂F₆, C₃F₈ or CF₄ as reaction gas, and depositing an oxide layer selected from a group consisted of TEOS, silicon nitride with TEOS, BPSG and polysilicon which has been oxidized.

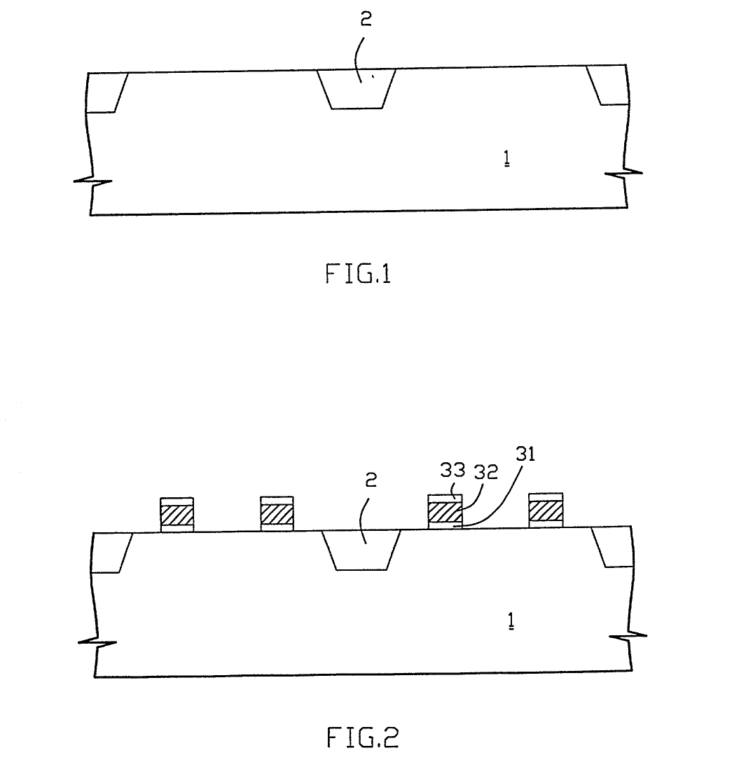

The formation of a word line 3 is shown in FIGS. 2 and 3, and will be described. Firstly, as shown in FIG. 2, forming a gate oxide layer with a thickness about 100˜250 angstroms, for example, through thermal oxidation method, on the substrate 1 and the oxide isolation regions 2. A layer of first conductive material, for example, a layer of polysilicon is deposited on the gate oxide layer, by LPCVD (Low Pressure Chemical Vapor Deposition) to a thickness of between about 2000-3000 angstroms. This layer is doped by ion implanting with phosphorous or arsenic ions at a dosage of between about 5 E 15 and 2 E 16 atom/cm², and an energy of between about 20 and 60 Kev., or may be doped in situ by the addition of dopant gases such as phosphine during deposition. Alternately, doping could be accomplished by diffusion using phosphorus oxychloride (POCl₃) at a temperature of between about 875° C. and 900° C., for between about 30 and 50 minutes. Then, A silicon nitride layer is formed on the polysilicon layer by LPCVD, plasma enhanced CVD or high density plasma CVD methods, utilizing SiH₄, NH₃, N₂ and N₂O or SiH₂Cl₂, NH₃, N₂ and N₂O as reaction gases. The preferable temperature is 400˜500° C. when employing CVD method. While the preferable temperature is 500˜800° C. when employing low pressure CVD method. The gate oxide layer, doped polysilicon layer and silicon nitride layer are then patterned by conventional photolithography and etching method to form two gate structures between two oxide isolation regions 2, and each of the gate structure is consisted of a gate oxide 31, a polysilicon gate 32 and a cap layer 33 of silicon nitride.

Subsequently, referring to FIG. 3, a source/drain region 34 is formed beside the gate structure nearby the oxide isolation region 2, and a source/drain region 36 is formed between the two adjacent gate structures and is shared by thereof, through ion implanting with an N+ dopant such as phosphorus P31 or arsenic As75 at a concentration of between about 2 E 15 and 1 E 16 atom/cm², and at an energy of between about 20 and 70 Kev. It is well understood by those skilled in the art that opposite dopants may be used, i.e., the substrate could be doped N− and the source/drain region made P+, without changing the scope of the invention. Thereafter, forming a silicon nitride layer on the cap layer 33 of silicon nitride, which can be formed by way of the above-mentioned method for the cap layer 33. Then, anisotropic etching with a gas such as CF₄+O₂ (carbon tetrafluoride and oxygen) or CF₄+H₂ (carbon tetrafluoride and hydrogen) is used to form a silicon nitride spacer 38 on each sidewall of the gate oxide 31, the polysilicon gate 32 and the cap layer 33 of silicon nitride. Thereby, a MOS transistor 3 for word line is provided.

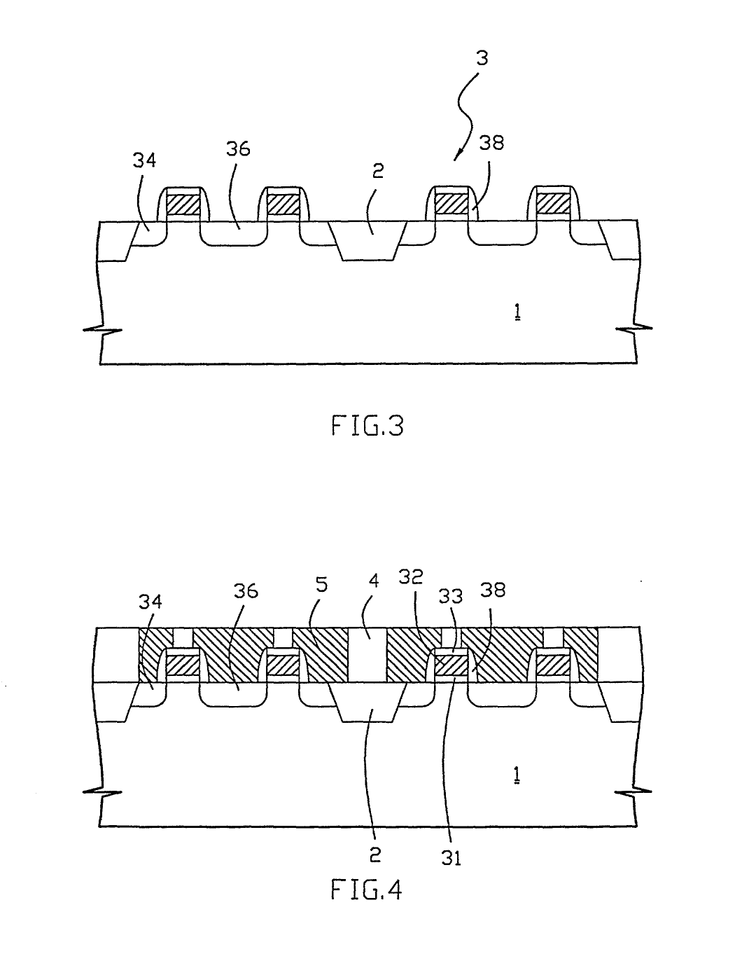

Referring to FIG. 4, then, a first oxide layer is formed on the MOS transistor 3 of word line. The first oxide layer can be formed by depositing an oxide material selected from a group consisted of TEOS, silicon nitride with TEOS, BPSG and polysilicon which has been oxidized, and planarized by chemical mechanical polishing (CMP) method. The first oxide layer is patterned by conventional photolithography and etching method to form a plurality of patterned first oxide 4, each of which is formed on each of the oxide isolation region 2 an each of the MOS transistor 3. Thereafter, a second conductive layer 5, for example, a polysilicon layer or a doped polysilicon layer, is deposited on the first oxides 4 and is etched back to the level of the first oxides 4. However, the second conductive layer 5 can be omitted.

The formation of bit line is shown in FIG. 5, with reference to FIG. 5, a third conductive layer, for example, a doped polysilicon layer and a layer of silicon nitride are sequentially formed on the first oxides 4. The doped polysilicon layer and the silicon nitride layer are formed by way of the method as the same with the above-mentioned for MOS transistor 3. Then, the doped polysilicon layer and the silicon nitride layer are patterned to form a plurality of conductive regions 6 of MOS-like structure consisted of a polysilicon gate 61 and a cap layer 62 of silicon nitride, for bit line. Each of the conductive regions 6 of MOS-like structure is across over each of the first oxides 4 on the two adjacent MOS transistor 3. Afterward, a silicon nitride spacer 63 is formed, by way of the above-mentioned, on each sidewall of the conductive region 6 of MOS-like structure.

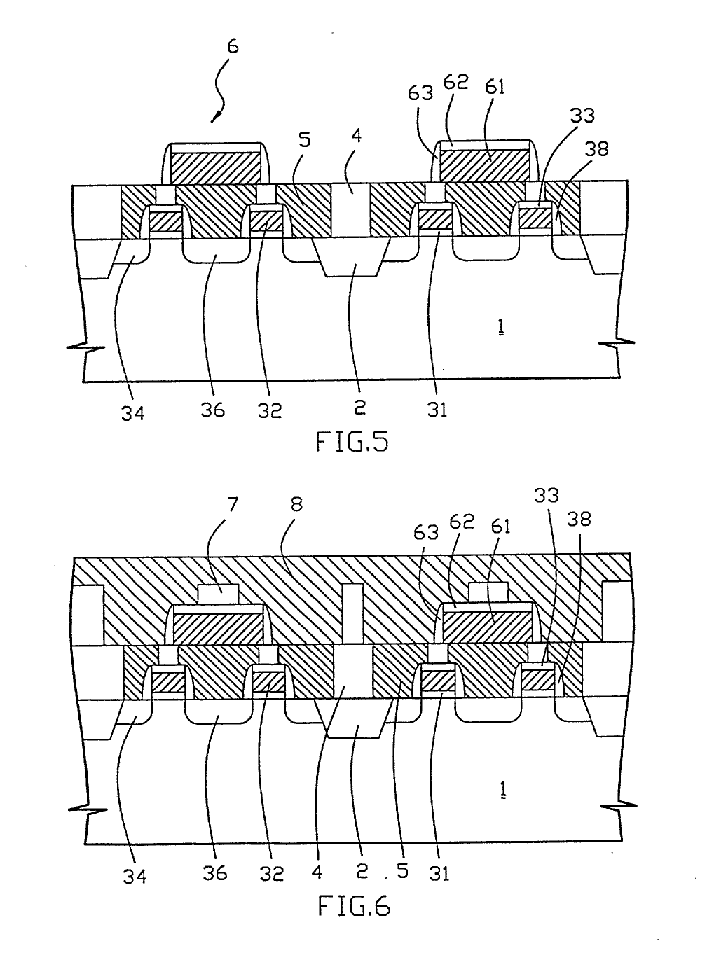

Subsequently, referring to FIG. 6, a second oxide layer is formed on the conductive regions 6 of MOS-like structure of bit line. The second oxide layer can be formed by depositing an oxide material selected from a group consisted of TEOS, silicon nitride with TEOS, BPSG and polysilicon which has been oxidized, and planarized by chemical mechanical polishing (CMP) method. The second oxide layer is patterned by conventional photolithography and etching method to form a plurality of patterned second oxides 7. Each of the second oxides 7 is formed on each of the first oxides 4 on each of the oxide isolation region 2 and each of the conductive regions 6 of MOS-like structure. Thereafter, a fourth conductive layer 8, for example, a polysilicon layer or doped polysilicon layer, is deposited on the second oxides 7 and is planarized by chemical mechanical polishing (CMP) method.

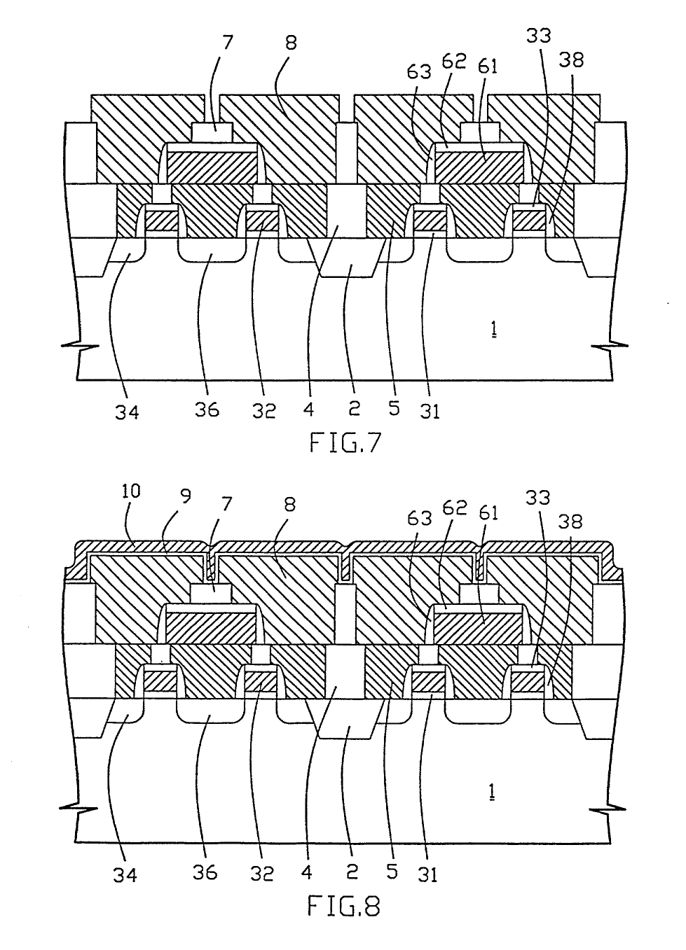

Referring to FIG. 7, the fourth conductive layer 8 is patterned by conventional photolithography and etching method to form a plurality of first electrodes for stack capacitors. Each of the first electrodes is comprised of two inversed U-shaped conductive regions 8. Alternately, the first electrode also can be an inversed U-shaped conductive region across over the two second oxides 7 each of which is formed on the first oxide 4 on the oxide isolation region 2.

Thereafter, referring to FIG. 8, a capacitor dielectric 9 is conformally formed on the surface of the first electrode. There are several materials that are suitable for the dielectric, such as ON (oxide-nitride), ONO (oxide-nitride-oxide), or Ta₂O₅ (tantalum oxide). The preferred dielectric material is formed of ONO to a thickness of between 30 and 90 angstroms. The bottom oxide is formed by exposure in DI (deionized) water to form an oxide with a thickness of between about 20 and 40 angstroms. The middle nitride is formed by LPCVD at a temperature of about 760° C., a pressure of 350 mtorr, in NH₃ (ammonia) and SiH₄ (silane), to a thickness of between about 20 and 50 Angstroms. The top oxide is formed by oxidation in a dry oxygen ambient, at a temperature of about 850° C., for about 30 minutes. Then, a fifth conductive layer 10, for example, a polysilicon layer or a doped polysilicon layer, is conformally formed on the capacitor dielectric 9, serving for a second electrode of the stack capacitor. Thereby, a self-aligned DRAM cell with a stack capacitor is obtained.

Accordingly, the present invention provides a self-aligned DRAM cell with a stack capacitor, in which the node contact of the storage capacitor and the MOS-like transistor for bit line are formed by self-alignment. In addition, a silicon nitride spacer is formed on each of sidewalls of the MOS-like transistor for bit line to prevent short circuit occurred between the MOS-like structure and the first electrode of the stack capacitor.

The above embodiments are only used to illustrate the present invention, not intended to limit the scope thereof. Many modifications of the above embodiments can be made without departing from the spirit of the present invention.

What is claimed is:

1. A method of forming a stack capacitor for a DRAM cell, comprising:
providing a semiconductor substrate having a plurality of oxide isolation regions formed thereon;
sequentially forming a gate oxide layer, a first conductive layer and a first silicon nitride layer on said substrate;
patterning said gate oxide layer, said first conductive layer and said first silicon nitride layer to form two MOS gates between two said oxide isolation regions;
performing a dopant implantation to form a source/drain region besides each of said MOS gates in said substrate, to form two adjacent MOS transistors between two said oxide isolation regions, wherein said two adjacent MOS transistors share one said source/drain region formed therebetween;
forming a first silicon nitride spacer for each side of each of said MOS transistors;
forming a first oxide layer on said MOS transistors;
patterning said first oxide layer to form a plurality of first oxides, each of which formed on each of said oxide isolation regions and each of said MOS transistors;
sequentially forming a second conductive layer and a second silicon nitride layer on said first oxides;
patterning said second conductive layer and said second silicon nitride layer to form a plurality of conductive regions of MOS-like structure, each of which being across over two said first oxides between two said oxide isolation regions;
forming a second silicon nitride spacer for each side of each of said conductive regions of MOS-like structure;
forming a second oxide layer on said conductive regions of MOS-like structure;
patterning said second oxide layer to form a plurality of second oxides, each of second oxides formed on each of said first oxides on each of said oxide isolation regions;
forming a third conductive layer on said second oxides;
patterning said third conductive layer to form a plurality of first capacitor electrodes, each of which formed between two said second oxides;
forming a conformal dielectric layer on said first capacitor electrodes as capacitor dielectric; and
forming a conformal fourth conductive layer on said dielectric layer to form a plurality of second capacitor electrode.

2. The method of claim 1, wherein further comprising forming and planarizing a fifth conductive layer on said first oxides prior to forming said conductive regions of MOS-like structure.

3. The method of claim 1, wherein said first conductive layer comprises polysilicon.

4. The method of claim 1, wherein said second conductive layer comprises polysilicon.

5. The method of claim 1, wherein said third conductive layer comprises polysilicon.

6. The method of claim 1, wherein said fourth conductive layer comprises polysilicon.

7. The method of claim 2, wherein said fifth conductive layer comprises polysilicon.

8. The method of claim 1, wherein the material of said capacitor dielectric is selected from a group consisted of ON (oxide-nitride), ONO (oxide-nitride-oxide) and Ta₂O₅ (tantalum oxide).

9. The method of claim 1, wherein said oxide isolation regions are formed of a plurality of field oxides.

10. The method of claim 1, wherein said oxide isolation regions are formed of a plurality of shallow trench isolations.

11. A method of forming a stack capacitor for a DRAM cell, comprising:
providing a semiconductor substrate having a plurality of oxide isolation regions formed thereon;
sequentially forming a gate oxide layer, a first conductive layer and a first silicon nitride layer on said substrate;
patterning said gate oxide layer, said first conductive layer and said first silicon nitride layer to form two MOS gates between two said oxide isolation regions;
performing a dopant implantation to form a source/drain region besides each of said MOS gates in said substrate, to form two adjacent MOS transistors between two said oxide isolation regions, wherein said two adjacent MOS transistors share one said source/drain region formed therebetween;
forming a first silicon nitride spacer for each side of each of said MOS transistors;
forming a first oxide layer on said MOS transistors;
patterning said first oxide layer to form a plurality of first oxides, each of which formed on each of said oxide isolation regions and each of said MOS transistors;
sequentially forming a second conductive layer and a second silicon nitride layer on said first oxides;
patterning said second conductive layer and said second silicon nitride layer to form a plurality of conductive regions of MOS-like structure, each of which being across over two said first oxides between two said oxide isolation regions;
forming a second silicon nitride spacer for each side of each of said conductive regions of MOS-like structure;
forming a second oxide layer on said conductive regions of MOS-like structure;
patterning said second oxide layer to form a plurality of second oxides, each of second oxides formed on each of said first oxides on each of said oxide isolation regions and each of said conductive regions of MOS-like structure;
forming a third conductive layer on said second oxides;
patterning said third conductive layer to form a plurality of first capacitor electrodes, each of said patterned third conductive regions formed between two adjacent said second oxides;
forming a conformal dielectric layer on said first capacitor electrodes as capacitor dielectric; and
forming a conformal fourth conductive layer on said dielectric layer to form a plurality of second capacitor electrodes.

12. The method of claim 1 1, wherein further comprising forming and planarizing a fifth conductive layer on said first oxides prior to forming said conductive regions of MOS-like structure.

13. The method of claim 11, wherein said first conductive layer comprises polysilicon.

14. The method of claim 11, wherein said second conductive layer comprises polysilicon.

15. The method of claim 11, wherein said third conductive layer comprises polysilicon.

16. The method of claim 11, wherein said fourth conductive layer comprises polysilicon.

17. The method of claim 12, wherein said fifth conductive layer comprises polysilicon.

18. The method of claim 1 1, wherein the material of said capacitor dielectric is selected from a group consisted of ON (oxide-nitride), ONO (oxide-nitride-oxide) and Ta₂O₅ (tantalum oxide).

19. The method of claim 11, wherein said oxide isolation regions are formed of a plurality of field oxides.

20. The method of claim 11, wherein said oxide isolation regions are formed of a plurality of shallow trench isolations.

21. A self-aligned DRAM cell with a stack capacitor, comprising:
a semiconductor substrate having a plurality of oxide isolation regions formed thereon;
a plurality of MOS transistors, each two said adjacent MOS transistors formed between two said oxide isolation regions, wherein said two adjacent MOS transistors share one source/drain region therebetween;
a plurality of first oxides, each of which formed on each of said oxide isolation regions and each of said MOS transistors;
a plurality of conductive regions of MOS-like structure each of which formed across over two said first oxides respectively formed on each of two said adjacent MOS transistors;
a plurality of second oxides each of which formed on each of said first oxides formed on each of said oxide isolations and each of said conductive regions of MOS-like structure; and
a plurality of stack capacitors each of which formed between two said oxide isolation regions.

22. The self-aligned DRAM cell of claim 21, wherein said MOS transistor is comprised of a gate oxide, a polysilicon gate, a cap layer of silicon nitride and a spacer of silicon nitride.

23. The self-aligned DRAM cell of claim 21, wherein said conductive region of MOS-like structure is comprised of a polysilicon gate, a cap layer of silicon nitride and a spacer of silicon nitride.

24. The self-aligned DRAM cell of claim 21, wherein each of two electrodes of said stack capacitor is made of polysilicon.

25. The self-aligned DRAM cell of claim 21, wherein the capacitor dielectric of each of said stack capacitors is made of a material selected from a group consisted of ON (oxide-nitride), ONO (oxide-nitride-oxide) and Ta₂O₅ (tantalum oxide).

26. The self-aligned DRAM cell of claim 21, wherein said oxide isolation regions are formed of a plurality of field oxides.

27. The self-aligned DRAM cell of claim 21, wherein said oxide isolation regions are formed of a plurality of shallow trench isolations.

28. The self-aligned DRAM cell of claim 21, wherein said stack capacitor is provided with two electrodes of inversed U shape.

29. The self-aligned DRAM cell of claim 21, wherein said stack capacitor is provided with two electrodes of inversed double-U shape.
